(19) United States
(12) Patent Application Publication
(10) Pub. No.: US 2023/0335674 A1
(43) Pub. Date: Oct. 19, 2023

(54) SEMICONDUCTOR LIGHT-EMITTING ELEMENT AND DISPLAY DEVICE COMPRISING SAME

(71) Applicant: LG ELECTRONICS INC., Seoul (KR)

(72) Inventors: Chilkeun PARK, Seoul (KR); Wonjae CHANG, Seoul (KR); Junghoon KIM, Seoul (KR)

(73) Assignee: LG ELECTRONICS INC., Seoul (KR)

(21) Appl. No.: 18/028,603

(22) PCT Filed: Sep. 28, 2020
(86) PCT No.: PCT/KR2020/013208

§ 371 Date: Mar. 27, 2023

(51) Int. Cl. H01L 33/20; H01L 25/075; H01L 33/44

(52) U.S. Cl. CPC H01L 33/20; H01L 25/0753; H01L 33/44; H01L 2933/0025

(57) ABSTRACT

The embodiment relates to a semiconductor light emitting device and a display device including the same. The semiconductor light emitting device according to the embodiment can include the second electrode layer 120, the light emitting structure 110 disposed on the second electrode layer 120, a protruding mesa semiconductor layer 100P disposed on the light emitting structure 110 and a passivation layer 130 disposed on a side surface of the light emitting structure 110. The protruding mesa semiconductor layer 100P can include a first conductivity type mesa semiconductor layer 111b and an undoped mesa semiconductor layer 105b.

### TECHNICAL FIELD

Embodiment relates to a semiconductor light emitting device and a display device including the same.

### BACKGROUND ART

Technologies for implementing large-area displays include liquid crystal displays (LCD), OLED displays, and Micro-LED displays.

A micro-LED display is a display using a micro-LED, which is a semiconductor light emitting device having a diameter or cross-sectional area of 100 μm or less, as a display device.

Since the micro-LED display uses micro-LED, which is a semiconductor light emitting device, as a display device, micro-LED displays have excellent performance in many characteristics, such as contrast ratio, response speed, color reproduction rate, viewing angle, brightness, resolution, lifespan, luminous efficiency or luminance.

In particular, the micro-LED display has the advantage of being able to freely adjust the size or resolution as the screen can be separated and combined in a modular manner, and can implement a flexible display.

However, since a large-scale micro-LED display requires millions of micro-LEDs, there is a technical problem in that it is difficult to quickly and accurately transfer micro-LEDs to a display panel.

Recently developed transfer technology includes a pick and place process, a laser lift-off method (LLO), or a self-assembly method.

Among them, the self-assembly method is a method in which a semiconductor light emitting device finds an assembly position by itself in a fluid, and is advantageous for implementing a large-screen display device.

Recently, although a micro-LED structure suitable for self-assembly has been proposed in U.S. Pat. No. 9,825,202, research on a technology for manufacturing a display through self-assembly of micro-LEDs is still insufficient.

In particular, in the case of rapidly transferring millions or more semiconductor light emitting devices to a large display in the prior art, the transfer speed can be improved, but there is a technical problem in that a transfer error rate can increase and a transfer yield can decrease.

On the other hand, the conventional micro-LED chip structure is manufactured in a mesa shape, and micro-sized chip production is required in TV, VR, and AR technologies using micro LED.

Accordingly, there is a problem in facing the limitation of the physical area to form the p-electrode layer and the n-electrode layer on the same surface on the mesa structure of the conventional micro-LED chip.

In particular, as the chip size required for next-generation micro-LED TV technology is reduced to about 10 μm or less, which is a subminiature size, according to the prior art, it is not easy to implement a pattern due to limitations in the physical area for forming the mesa and the n-electrode metal layer, and the manufacturing cost increases due to the increase in the process cost for forming the fine pattern.

In particular, as the chip size required for AR/VR technology is smaller (about 5 μm or less), there is a problem in facing the limitation of the physical area for implement the shape of the light emitting chip.

Also, in the conventional micro-LED chip, by forming a mesa structure in the p-GaN area, the area of the active layer emitting light is smaller than the area of the LED chip, resulting in a decrease in luminous efficiency.

Also, in order to improve the competitiveness of micro-LED displays, it is necessary to improve the light extraction efficiency of semiconductor light emitting device packages along with high transfer efficiency. However, to improve light extraction efficiency in a conventional LED package, it is common to use a light extraction structure such as PSS (Patterned Sapphire Substrate). However, the conventional PSS structure is formed on a sapphire substrate, which is a growth substrate. When the growth substrate remains, there is a problem in that it is difficult to apply to an ultra-thin micro-LED display as the thickness of the micro-LED package becomes thick.

### DISCLOSURE

### Technical Problem

One of the technical objects of the embodiment is to provide a semiconductor light emitting device having a compact size capable of simultaneously improving transfer speed and transfer yield in transferring semiconductor light emitting devices to a display panel and increasing transfer and assembly efficiency without position confusion during direct self-assembly and a display device including the same.

Also, one of the technical objects of the embodiment is to provide a semiconductor light emitting device capable of maximizing luminous efficiency and providing an ultra-small size micro LED chip structure having an ultra-high-speed direct self-assembly transfer function using an electromagnetic field and a display device including the same.

Also, one of the technical objects of the embodiment is to provide a semiconductor light emitting device capable of maximizing luminous efficiency with side-effects of a subminiature LED chip and a display device including the same, as well as a structure resistant to collisions between chips and external shocks during self-assembly.

Also, one of the technical objects of the embodiment is to provide a semiconductor light emitting device package capable of improving light extraction efficiency while implementing an ultra-thin micro-LED display and a display device including the same.

The technical objects of the embodiment are not limited to those described in this section, and include those that can be understood through the description of the invention.

### Technical Solution

The semiconductor light emitting device according to the embodiment can include the second electrode layer 120 and the light emitting structure 110 disposed on the second electrode layer 120, a protruding mesa semiconductor layer 100P disposed on the light emitting structure 110 and a passivation layer 130 disposed on a side surface of the light emitting structure 110. The protruding mesa semiconductor layer 100P can include a first conductivity type mesa semiconductor layer 111b and an undoped mesa semiconductor layer 105b.

The second electrode layer 120 can include a transparent electrode layer 121 disposed on the light emitting structure 110, a reflective layer 122 disposed on the transparent electrode layer 121, and a magnetic layer 123 disposed on the reflective layer 122.

The horizontal width W2 of the protruding mesa semiconductor layer 100P can be smaller than the horizontal width W1 of the light emitting structure 110.

The horizontal width W2 of the protruding mesa semiconductor layer 100P can be smaller than the horizontal width W3 of the second electrode layer 120.

The horizontal width W2 of the protruding mesa semiconductor layer 100P is smaller than the horizontal width W1 of the light emitting structure 110 or the horizontal width W3 of the second electrode layer 120, the second electrode layer 120 can include a magnetic material, and the protruding mesa semiconductor layer 100P may not include a magnetic material.

The height H2 of the protruding mesa semiconductor layer 100P can be smaller than the height H1 of the light emitting structure 110.

In the light emitting structure 110, the horizontal width W1 of the active layer 112 can be greater than the horizontal width W3 of the second electrode layer 120.

The passivation layer 130 can be disposed on a side surface of the second conductivity type semiconductor layer 113 of the light emitting structure and a part of the side surface and bottom surface of the second electrode layer 120.

The protruding mesa semiconductor layer 100P disposed on the light emitting structure 110 can improve light extraction efficiency by a photonic crystal function.

The embodiment can further include a light extraction structure 140 disposed on a side surface of the protruding mesa semiconductor layer 100P.

As the light extraction structure 140 includes a reflective material of a metallic material, and the first pad electrode 221 contacts the light extraction structure 140, the light extraction structure 140 can be electrically connected to the first conductivity type semiconductor layer 111 of the light emitting structure.

The embodiment can further include a second solder layer 160 disposed below the second electrode layer 120.

The display device according to the embodiment can include a panel substrate 110 including a first wiring electrode 121 and a second wiring electrode 122, and any one of the semiconductor light emitting device packages disposed on the panel substrate.

### Effects of the Invention

According to the semiconductor light emitting device and the display device including the same according to the embodiment, in transferring semiconductor light emitting devices to a display panel, there is a technical effect of simultaneously improving transfer speed and transfer yield and as the protruding mesa structure is disposed in the opposite area of p-GaN, there is a technical effect of increasing transfer and assembly efficiency without position crosstalk during direct self-assembly.

Also, according to the embodiment, the light emitting area of the light emitting device chip can be implemented as the maximum area and a structure having a highly reflective metal layer is implemented, there is a technical effect capable of providing a micro LED chip structure having an ultra-high-speed direct self-assembly transfer function using an electromagnetic field, also maximizing the luminous efficiency.

Also, according to the embodiment, the passivation layer is formed on the side surface of the second conductivity type semiconductor layer and a part of the side surface and bottom surface of the second electrode layer, thereby providing a structure resistant to collision between chips and external impact during self-assembly.

Also, according to the embodiment, by forming the passivation layer on the top and side surfaces of the p-GaN area of the light emitting chip, there is a technical effect of maximizing light emitting efficiency with side-effects of the subminiature LED chip.

Also, according to the embodiment, there is a technical effect that can improve light extraction efficiency while implementing an ultra-thin micro-LED display.

Specifically, the semiconductor light emitting device 150R according to the embodiment can have a chip structure for Direct Self Assembly Transfer (DSAT) using an electromagnetic field.

For example, the semiconductor light emitting device 150R according to the embodiment forms a transparent electrode layer 121 and a reflective layer 122 which are the second electrode layer 120 in a total area of p-GaN area which is the second conductivity type semiconductor layer 113 and forms a magnetic layer 123 of an electromagnetic material on the reflective layer 122. And, the mesa-shaped protruding mesa semiconductor layer 100P on the opposite side of the p-GaN area can be implemented in a smaller size than the chip size, and the passivation layer 130 can be formed on the top and side surfaces of the p-GaN area of the chip.

Also, according to the embodiment, it is possible to solve the problem faced by the limitations of the physical area for forming the Mesa shape and the p/n-electrode layer on the same surface for the production of ultra-small size chips required for TV and VR/AR technology.

According to another embodiment, in transferring the semiconductor light emitting devices to the display panel, it is possible to simultaneously improve transfer speed and transfer yield, as the protruding mesa structure is disposed in the area opposite to p-GaN, there is a technical effect of increasing transfer and assembly efficiency without position crosstalk during direct self-assembly.

For example, in the embodiment, the horizontal width W2 of the protruding mesa semiconductor layer 100P can be smaller than the horizontal width W1 of the light emitting structure 110 or the horizontal width W3 of the second electrode layer 120. Also, for example, the horizontal width W2 of the mesa semiconductor layer 100P can be formed as the horizontal width W1 of the light emitting structure 110 or can be formed in a range of ¼ to ⅔, or ⅓ to ½ of the horizontal width W3 of the second electrode layer 120.

According to the embodiment, since the horizontal width W2 of the protruding mesa semiconductor layer 100P is smaller than the horizontal width W1 of the light emitting structure 110 or the horizontal width W3 of the second electrode layer 120, during direct self-assembly, transfer and assembly efficiency can be increased without position confusion. Accordingly, in transferring the semiconductor light emitting devices to the display panel, it is possible to simultaneously improve the transfer speed and the transfer yield.

Also, according to the embodiment, as the horizontal width W2 of the protruding mesa semiconductor layer 100P is smaller than the horizontal width W1 of the light emitting structure 110 or the horizontal width W3 of the second electrode layer 120 and the second electrode layer 120 contains a magnetic material, but the protruding mesa semiconductor layer 100P does not contain a magnetic material, due to the mesa-shaped structure and material characteristics, there is a technical effect of increasing transfer and assembly efficiency without positional confusion during direct self-assembly.

Also, according to the embodiment, since the height H2 of the protruding mesa semiconductor layer 100P is smaller than the height H1 of the light emitting structure 110, transfer and assembly efficiency can be increased without positional confusion during direct self-assembly, and by minimizing the etching range of the first conductivity-type semiconductor layer 111 in the light emitting structure, there is a technical effect of improving internal light emitting efficiency by maintaining the epi characteristics of the light emitting structure.

Also, according to the embodiment, in the light emitting structure 110, the horizontal width W1 of the active layer 112 is larger than the horizontal width W3 of the second electrode layer 120, so that the light emitting area of the light emitting device chip can be realized as the maximum area, and by implementing a structure having a highly reflective metal layer, there is a technical effect capable of providing an ultra-small size micro LED chip structure having a high-speed direct self-assembly transfer function using an electromagnetic field as well as maximizing luminous efficiency.

Also, according to the embodiment, as the passivation layer 130 is formed on the side surface of the second conductivity type semiconductor layer 113 and part of the side surface and bottom surface of the second electrode layer 120, not only does it have a structure that is resistant to collisions between chips and external shocks during self-assembly, but it also has a technical effect that can maximize luminous efficiency with the side-effects of the ultra-small LED chip.

Also, according to the embodiment, by forming the passivation layer 130 on the top and side surfaces of the p-GaN area of the light emitting chip, there is a technical effect of maximizing light emitting efficiency with side-effects of the subminiature LED chip.

The technical effects of the embodiments are not limited to those described in this section, and include those that can be understood through the description of the invention.

### BRIEF DESCRIPTION OF THE DRAWING

FIG. 1 is an exemplary view in which a display device 100 according to an embodiment is disposed in a living room together with a washing machine 10, a robot cleaner 20, and an air purifier 30.

FIG. 2 is an enlarged view of the first panel area A1 in the display device 100 of FIG. 1.

FIG. 3 is a view showing an example in which the semiconductor light emitting device 150R according to the embodiment is assembled on the substrate 200 by a self-assembly method.

FIG. 4 is a cross-sectional view of a package in which a semiconductor light emitting device 150R according to an embodiment is assembled on a substrate 200.

FIG. 5 is a detailed view of a semiconductor light emitting device 150R in the semiconductor light emitting device package shown in FIG. 4 according to an embodiment.

FIGS. 6A to 6H are cross-sectional views of the manufacturing method of the semiconductor light emitting device according to the embodiment.

FIG. 7 is a cross-sectional view of a semiconductor light emitting device 150R2 according to a second embodiment.

FIG. 8 is a cross-sectional view of a semiconductor light emitting device 150R3 according to a third embodiment.

### MODE FOR INVENTION

Hereinafter, the embodiments disclosed in the present specification will be described in detail with reference to the accompanying drawings, but the same or similar components are given the same reference sign regardless of the reference numerals, and the redundant description thereof will be omitted. The suffixes “module” and “part” for components used in the following description are given or mixed in consideration of only the ease of writing the specification, and do not have a meaning or role distinct from each other by themselves. Also, the accompanying drawings are for easy understanding of the embodiments disclosed in the present specification, and the technical spirit disclosed in the present specification is not limited by the accompanying drawings. Also, when an element, such as a layer, area, or substrate, is referred to as being ‘on’ another component, this includes that it is directly on the other element or there can be other intermediate elements in between.

The display device described in this specification can include a mobile phone, a smart phone, a laptop computer, a Digital broadcasting terminals, a personal digital assistants (PDA), a portable multimedia player (PMP), a navigation, a slate PC, a tablet PC, an ultra-book, a digital TV, a desktop computer, etc. However, the configuration according to the embodiment described in the present specification can be applied to a device capable of displaying even a new product form to be developed later.

Hereinafter, a semiconductor light emitting device according to an embodiment and a display device including the same will be described.

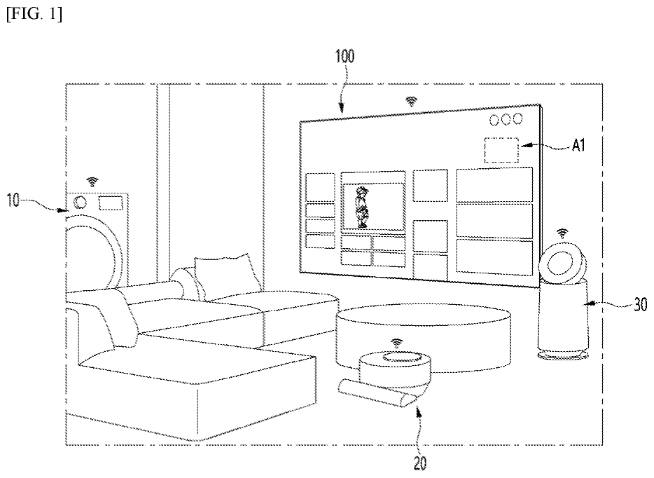

FIG. 1 is an exemplary view in which a display device 100 according to an embodiment is disposed in a living room together with a washing machine 10, a robot cleaner 20, an air purifier 30, and the like.

The display device 100 of the embodiment can display the status of various electronic products such as the washing machine 10, the robot cleaner 20, and the air purifier 30 and can communicate with each electronic product based on IOT and can control each electronic product based on user's setting data.

The display device 100 according to the embodiment can include a flexible display fabricated on a thin and flexible substrate. The flexible display can be bent or rolled like paper while maintaining characteristics of a conventional flat panel display.

In the flexible display, visual information can be implemented by independently controlling light emission of unit pixels arranged in a matrix form. The unit pixel means a minimum unit for implementing one color. A unit pixel of the flexible display can be implemented by a semiconductor light emitting device. In the embodiment, the semiconductor light emitting device can be a Micro-LED, but is not limited thereto.

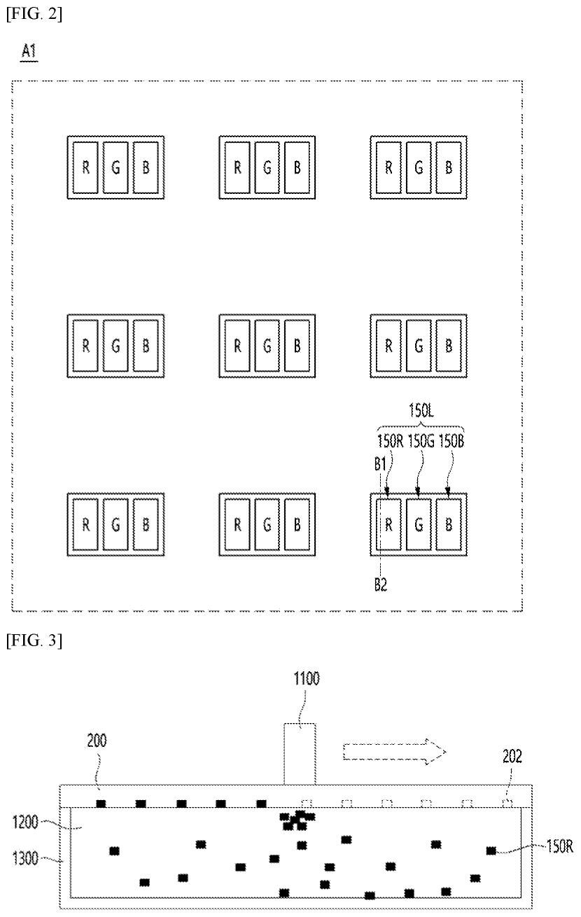

Next, FIG. 2 is an enlarged view of the first panel area A1 in the display device 100 of FIG. 1.

Referring to FIG. 2, the display device 100 according to the embodiment can be manufactured by mechanically and electrically connecting a plurality of panel areas such as the first panel area A1 by tiling.

The first panel area A1 can include a plurality of unit pixels 150L, and each unit pixel 150L can include a first semiconductor light emitting device 150R, a second semiconductor light emitting device 150G, and a third semiconductor light emitting device 150B as sub-pixels. The first, second, and third semiconductor light emitting devices 150R, 150G, and 150B can be a red light emitting device (R), a green light emitting device (G), and a blue light emitting device (B), respectively, but are not limited thereto.

Hereinafter, the first semiconductor light emitting device 150R will be mainly described, and the remaining second and third semiconductor light emitting devices 150G and 150B can also adopt the technical features of the first semiconductor light emitting device 150R, and hereinafter, the ‘first semiconductor light emitting device according to the embodiment’ will be referred to as ‘semiconductor light emitting device according to the embodiment’.

In the embodiment, each semiconductor light emitting device can be driven in an active matrix (AM) method or a passive matrix (PM) method.

### First Embodiment

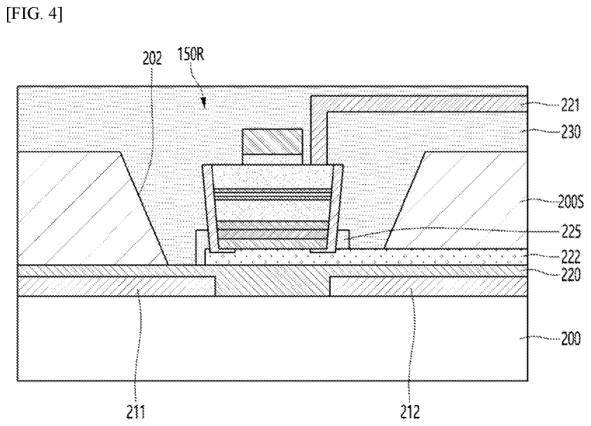

Next, FIG. 3 is a view showing an example in which the semiconductor light emitting device 150R according to the first embodiment is assembled on the substrate 200 by a self-assembly method. FIG. 4 is a cross-sectional view of a package in which the semiconductor light emitting device 150R according to the first embodiment is assembled on the substrate 200 (hereinafter, the ‘first embodiment’ will be referred to as ‘embodiment’).

Referring to FIGS. 3 and 4, an example in which the semiconductor light emitting device 150R according to the embodiment is assembled to the substrate 200 by a self-assembly method using an electromagnetic field will be described.

In FIG. 3, the substrate 200 may be a panel substrate of a display device or a temporary donor substrate for transfer.

In the following description, the substrate 200 is described as a panel substrate of a display device, but the embodiment is not limited thereto.

The substrate 200 can be formed of glass or polyimide. Also, the substrate 200 can include a flexible material such as polyethylene naphthalate (PEN) or polyethylene terephthalate (PET). Also, the substrate 200 can be a transparent material, but is not limited thereto.

Referring to FIG. 3, a semiconductor light emitting device 150R can be put into a chamber 1300 filled with a fluid 1200. The fluid 1200 can be water such as ultrapure water, but is not limited thereto.

After that, the substrate 200 can be disposed on the chamber 1300. Depending on the embodiment, the substrate 200 can be introduced into the chamber 1300.

Next, referring to FIG. 4, a pair of first electrodes 211 and a second electrode 212 corresponding to each of the semiconductor light emitting devices 150R to be assembled can be formed on the substrate 200.

The first electrode 211 and the second electrode 212 can be formed of a transparent electrode (ITO) or can include a metal material having excellent electrical conductivity. For example, the first electrode 211 and the second electrode 212 can be formed of at least one of Titanium (Ti), Chromium (Cr), Nickel (Ni), Aluminum (Al), Platinum (Pt), Gold (Au), tungsten (W) or molybdenum (Mo) or an alloy thereof.

The first electrode 211 and the second electrode 212 can function as a pair of assembly electrodes for fixing the semiconductor light emitting device 150R assembled in the assembly hole 202 on the substrate 200 by emitting an electric field when voltage is applied thereto.

As the distance between the first electrode 211 and the second electrode 212 is smaller than the width of the semiconductor light emitting device 150R and the width of the assembly hole 202, the assembly position of the semiconductor light emitting device 150R using an electric field can be more accurately fixed.

As the insulating layer 220 is formed on the first electrode 211 and the second electrode 212, the first electrode 211 and the second electrode 212 can be protected from the fluid 1200, and leakage of current flowing through the first electrode 211 and the second electrode 212 can be prevented. The insulating layer 220 can be formed of a single layer or multiple layers of an inorganic insulator such as silica or alumina or an organic insulator.

Also, the insulating layer 220 can include an insulating and flexible material such as polyimide, PEN, PET, or the like, and can be integrally formed with the substrate 200 to form a single substrate.

The insulating layer 220 may be an adhesive insulating layer or a conductive adhesive layer having conductivity. Since the insulating layer 220 is ductile, it can enable a flexible function of the display device.

A barrier wall 200S can be formed on an upper portion of the insulating layer 220. A partial area of the barrier wall 200S can be located above the first electrode 211 and the second electrode 212.

For example, when forming the substrate 200, as some of the barrier walls formed on the insulating layer 220 are removed, an assembly hole 202 in which each of the semiconductor light emitting devices 150R is assembled to the substrate 200 can be formed. A second pad electrode 222 can be formed between the barrier wall 200S and the insulating layer 220 to apply power to the semiconductor light emitting device 150R.

An assembly hole 202 to which the semiconductor light emitting devices 150R are coupled is formed in the substrate 200, and a surface on which the assembly hole 202 is formed can contact the fluid 1200. The assembly hole 202 can guide an accurate assembly position of the semiconductor light emitting device 150R.

Meanwhile, the assembling hole 202 can have a shape and size corresponding to the shape of the semiconductor light emitting device 150R to be assembled at the corresponding position. Accordingly, it is possible to prevent another semiconductor light emitting device from being assembled into the assembly hole 202 or from assembling a plurality of semiconductor light emitting devices.

Referring back to FIG. 3, after the substrate 200 is disposed, the assembly device 1100 including a magnetic material can move along the substrate 200. The assembly device 1100 can move while in contact with the substrate 200 in order to maximize the area of the magnetic field into the fluid 1200. Depending on the embodiment, the assembly device 1100 can include a plurality of magnetic bodies or can include a magnetic body having a size corresponding to that of the substrate 200. In this case, the moving distance of the assembling device 1100 can be limited within a predetermined range.

The semiconductor light emitting device 150R in the chamber 1300 can move toward the assembly device 1100 by the magnetic field generated by the assembly device 1100.

While moving toward the assembly device 1100, the semiconductor light emitting device 150R can enter the assembly hole 202 and come into contact with the substrate 200.

At this time, by the electric field applied by the first electrode 211 and the second electrode 212 formed on the substrate 200, the semiconductor light emitting device 150R in contact with the substrate 200 can be prevented from being separated by the movement of the assembly device 1100.

That is, by the self-assembly method using the above-described electromagnetic field, since the time required to assemble each of the semiconductor light emitting devices 150R to the substrate 200 can be drastically reduced, a large-area high-pixel display can be realized more quickly and economically.

Next, referring to FIG. 4, as a predetermined solder layer 225 is further formed between the semiconductor light emitting device 150R assembled on the assembly hole 202 of the substrate 200 and the second pad electrode 222, coupling force of the semiconductor light emitting device 150R can be improved.

Thereafter, the first pad electrode 221 is connected to the semiconductor light emitting device 150R to apply power.

Next, a molding layer 230 may be formed on the barrier wall 200S of the substrate 200 and the assembly hole 202. The molding layer 230 can be a transparent resin or a lane containing a reflective material or a scattering material.

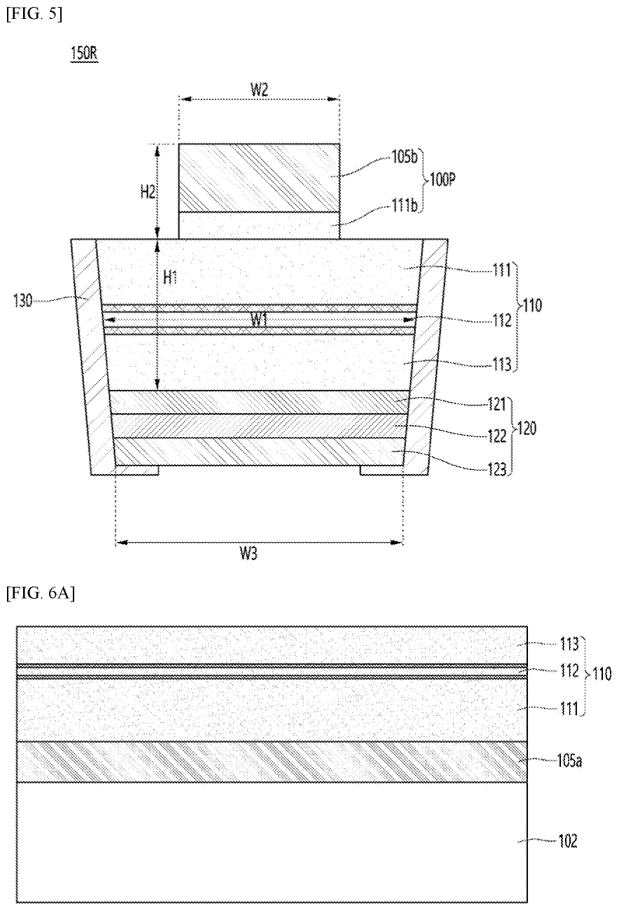

Next, FIG. 5 is a detailed view of the semiconductor light emitting device 150R according to the embodiment in the semiconductor light emitting device package shown in FIG. 4.

Referring to FIG. 5, as the semiconductor light emitting device 150R according to an embodiment can include a protruding mesa semiconductor layer 100P and the protruding mesa structure is disposed in the area opposite to p-GaN, transfer and assembly efficiency can be increased without position crosstalk during direct self-assembly. Accordingly, there is a technical effect that can simultaneously improve transfer speed and transfer yield in transferring semiconductor light emitting devices to a display panel.

Also, according to the embodiment, the light emitting area of the light emitting device chip can be implemented as the maximum area and a structure having a highly reflective metal layer is implemented, there is a technical effect capable of providing a micro LED chip structure with ultra-high-speed direct self-assembly and transfer function using an electromagnetic field, also maximizing the luminous efficiency.

Also, according to the embodiment, by forming the passivation layer on the upper and side surfaces of the p-GaN area of the light emitting chip, the embodiment not only has a structure resistant to collision between chips and external impact during self-assembly, but also has a technical effect of maximizing luminous efficiency due to side-effects of a subminiature LED chip.

Also, according to the embodiment, there is a technical effect of improving light extraction efficiency while implementing an ultra-thin micro-LED display.

The technical effect of this embodiment will be described in detail with reference to FIG.

FIG. 5 is a detailed view of a semiconductor light emitting device 150R according to an embodiment.

In the embodiment, the semiconductor light emitting devices 150R, 150G, and 150B are p-n junction diodes in which electrical energy is converted into light energy, and can be made of compound semiconductors containing elements of groups III and V on the periodic table and can implement various colors such as red, green, and blue by controlling the band gap energy by adjusting the composition ratio of the compound semiconductor.

The semiconductor light emitting device 150R according to the embodiment can include a second electrode layer 120, a light emitting structure 110, a protruding mesa semiconductor layer 100P, and a passivation layer 130. The protruding mesa semiconductor layer 100P can include a first conductivity type mesa semiconductor layer 111b and an undoped mesa semiconductor layer 105b.

The light emitting structure 110 can include a first conductivity type semiconductor layer 111, an active layer 112, and a second conductivity type semiconductor layer 113.

The first conductivity type semiconductor layer 111 can be implemented as a group III-group 5V compound semiconductor doped with a first conductivity type dopant. When the first conductivity-type semiconductor layer is an n-type semiconductor layer, the first conductivity-type dopant is an n-type dopant and can include Si, Ge, Sn, Se, or Te, but is not limited thereto.

The active layer 112 is a layer in which electrons injected through the first conductivity type semiconductor layer 111 and holes injected through the second conductivity type semiconductor layer 113 meet each other to emit light having energy determined by the bandgap energy inherent to the active layer material.

The active layer 112 can be formed of at least one of a single quantum well structure, a multi quantum well (MQW) structure, a quantum-wire structure, or a quantum dot structure.

The well layer/barrier layer of the active layer 112 can have a pair structure of one or more of InGaN/GaN, InGaN/InGaN, GaN/AlGaN, InAlGaN/GaN, GaAs (InGaAs)/AlGaAs, GaInP/AlGaInP, GaP/AlGaP, or InGaP/AlGaP, but is not limited thereto.

The second conductivity type semiconductor layer 113 can include a group 3-group 5 compound semiconductor doped with a second conductivity type dopant, for example, a semiconductor material having a composition formula of I InₓAl_{y}Ga_{1-x-y}N (0≤x≤1, 0≤y≤1, 0≤x+y≤1). When the second conductivity type semiconductor layer 113 is a p-type semiconductor layer, the second conductivity type dopant is a p-type dopant and can include Mg, Zn, Ca, Sr, Ba, or the like.

The second electrode layer 120 can include a transparent electrode layer 121, a reflective layer 122, and a magnetic layer 123.

The transparent electrode layer 121 can include at least one of indium tin oxide (ITO) and indium zinc oxide (IZO), IZTO (indium zinc tin oxide), IAZO (indium aluminum zinc oxide), IGZO (indium gallium zinc oxide), IGTO (indium gallium tin oxide), AZO (aluminum zinc oxide), ATO (antimony tin oxide), GZO (gallium zinc oxide), IZON (IZO Nitride), AGZO (Al—Ga ZnO), IGZO (In—Ga ZnO), ZnO, IrOx, RuOx, NiO, RuOx/ITO, Ni/IrOx/Au, or Ni/IrOx/Au/ITO, but is not limited to these materials.

The reflective layer 122 can include a reflective layer made of a metal layer including Al, Ag, or an alloy including Al or Ag.

Also, the reflective layer 122 can include one or more metals selected from among Ti, Al, Ag, TiAl, TiAlTi, TiAgTi, MoAl, MoAlMo, and MoAlTi in a single layer or multiple layers.

Also, the reflective layer 122 can include a junction metal such as Ti, Cr, Mo, or Pt.

Also, the magnetic layer 123 can include a metal having magnetism, such as nickel (Ni), but is not limited thereto.

One of the technical objects of the embodiment is to provide a semiconductor light emitting device of a subminiature size capable of simultaneously improving transfer speed and transfer yield in transferring semiconductor light emitting devices to a display panel and increasing transfer and assembly efficiency without positional confusion during direct self-assembly and a display device including the same.

For example, forming a p-electrode layer and an n-electrode layer on the same surface on the mesa structure of a conventional micro-LED chip faces a problem in which physical area is limited.

In particular, as the chip size required for next-generation micro-LED TV technology is reduced to about 10 μm or less, which is a subminiature size, in the related art, it is not easy to implement a pattern due to limitations in the physical area for forming the mesa and the n-electrode metal layer, and the manufacturing cost increases due to the increase in the process cost for forming the fine pattern.

In particular, since the chip size required for AR/VR technology is smaller (about 5 μm or less), there is a problem in that the physical area for realizing the light emitting chip shape is limited.

Also, one of the technical objects of the embodiment is to provide a semiconductor light emitting device capable of maximizing luminous efficiency and providing an ultra-small size micro LED chip structure having an ultra-high-speed direct self-assembly transfer function using an electromagnetic field and a display device including the same.

Also, one of the technical objects of the embodiment is to provide a semiconductor light emitting device capable of maximizing luminous efficiency with side-effects of a subminiature LED chip and a display device including the same, as well as a structure resistant to collisions between chips and external shocks during self-assembly.

Also, one of the technical objects of the embodiment is to provide a semiconductor light emitting device package capable of improving light extraction efficiency while implementing an ultra-thin micro-LED display and a display device including the same.

Also, one of the technical objects of the embodiment is to provide a semiconductor light emitting device package capable of improving light extraction efficiency while implementing an ultra-thin micro-LED display and a display device including the same, since the conventional light emitting device package has a problem in that the thickness increases as the growth substrate remains to improve the light extraction efficiency,

Referring to FIG. 5, the semiconductor light emitting device 150R according to the embodiment can include a mesa semiconductor layer 100P protruding on the light emitting structure 110, and the protruding mesa semiconductor layer 100P can include a first conductivity type mesa semiconductor layer 111b and an undoped mesa semiconductor layer 105b.

The semiconductor light emitting device 150R according to the embodiment may have a chip structure for Direct Self Assembly Transfer (DSAT) using an electromagnetic field.

For example, in the semiconductor light emitting device 150R according to the embodiment, a transparent electrode layer 121 as the second electrode layer 120 and a reflective layer 122 are formed on the entire area of the p-GaN area as the second conductivity type semiconductor layer 113, and a magnetic layer 123 of an electromagnetic material is formed on the reflective layer 122. Also, the mesa-shaped protruding mesa semiconductor layer 100P on the opposite side of the p-GaN area can be implemented in a size smaller than the chip size, and the passivation layer 130 can be formed on the top and side surfaces of the p-GaN area of the chip.

According to the embodiment, it is possible to solve the problem faced by the limitations of the physical area for forming the mesa shape and the p/n-electrode layer on the same surface for the production of ultra-small size chips required for TV and VR/AR technologies.

Also, according to the embodiment, in transferring the semiconductor light emitting devices to the display panel, the transfer speed and the transfer yield can be simultaneously improved, and as the protruding mesa structure is disposed in the area opposite to p-GaN, there is a technical effect of increasing transfer and assembly efficiency without position crosstalk during direct self-assembly.

For example, in the embodiment, the horizontal width W2 of the protruding mesa semiconductor layer 100P can be smaller than the horizontal width W1 of the light emitting structure 110 or the horizontal width W3 of the second electrode layer 120. Also, for example, the horizontal width W2 of the mesa semiconductor layer 100P can be formed as the horizontal width W1 of the light emitting structure 110 or can be formed in a range of ¼ to ⅔, or ⅓ to ½ of the horizontal width W3 of the second electrode layer 120.

According to the embodiment, as the horizontal width W2 of the protruding mesa semiconductor layer 100P is smaller than the horizontal width W1 of the light emitting structure 110 or the horizontal width W3 of the second electrode layer 120, during direct self-assembly, transfer and assembly efficiency can be increased without position confusion. Accordingly, in transferring the semiconductor light emitting devices to the display panel, it is possible to simultaneously improve the transfer speed and transfer yield.

Also, according to the embodiment, as the horizontal width W2 of the protruding mesa semiconductor layer 100P is smaller than the horizontal width W1 of the light emitting structure 110 or the horizontal width W3 of the second electrode layer 120 and the second electrode layer 120 contains a magnetic material, but the protruding mesa semiconductor layer 100P does not contain a magnetic material, due to the mesa-shaped structure and material characteristics, there is a technical effect of increasing transfer and assembly efficiency without positional confusion during direct self-assembly.

Also, according to the embodiment, since the height H2 of the protruding mesa semiconductor layer 100P is smaller than the height H1 of the light emitting structure 110, transfer and assembly efficiency can be increased without positional confusion during direct self-assembly, and by minimizing the etching range of the first conductivity-type semiconductor layer 111 in the light emitting structure, there is a technical effect of improving internal light emitting efficiency by maintaining the epi characteristics of the light emitting structure.

Also, according to the embodiment, in the light emitting structure 110, the horizontal width W1 of the active layer 112 is larger than the horizontal width W3 of the second electrode layer 120, so that the light emitting area of the light emitting device chip can be realized as the maximum area, and by implementing a structure having a highly reflective metal layer, there is a technical effect capable of providing an ultra-small size micro LED chip structure having a high-speed direct self-assembly transfer function using an electromagnetic field as well as maximizing luminous efficiency.

Also, according to the embodiment, by forming the protrusion type mesa semiconductor layer 100P on the relatively thick first conductivity type semiconductor layer 111 without forming a mesa structure on the second conductivity type semiconductor layer 113, there is a technical effect capable of improving internal light emitting efficiency as well as improving reliability by minimizing damage caused by etching of the light emitting structure 110.

Also, according to the embodiment, as the passivation layer 130 is formed on the side surface of the second conductivity type semiconductor layer 113 and part of the side surface and bottom surface of the second electrode layer 120, not only does it have a structure that is resistant to collisions between chips and external shocks during self-assembly, but it also has a technical effect that can maximize luminous efficiency with the side-effects of the ultra-small LED chip.

Also, according to the embodiment, by forming the passivation layer 130 on the top and side surfaces of the p-GaN area of the light emitting chip, there is a technical effect of maximizing light emitting efficiency with side-effects of the subminiature LED chip.

Also, according to the embodiment, by improving the light extraction efficiency by the photonic crystal effect by the protruding mesa semiconductor layer 100P disposed on the light emitting structure 110, there is a special technical effect that can improve light extraction efficiency while implementing an ultra-thin micro-LED display.

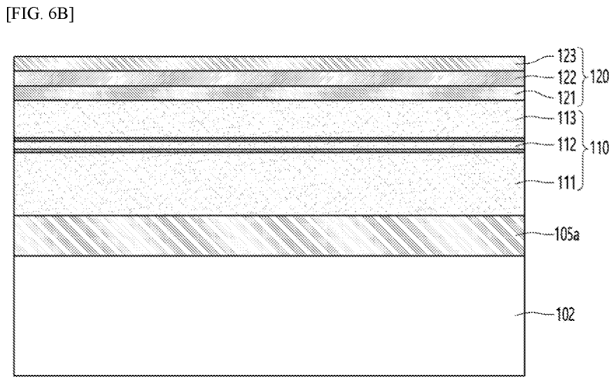

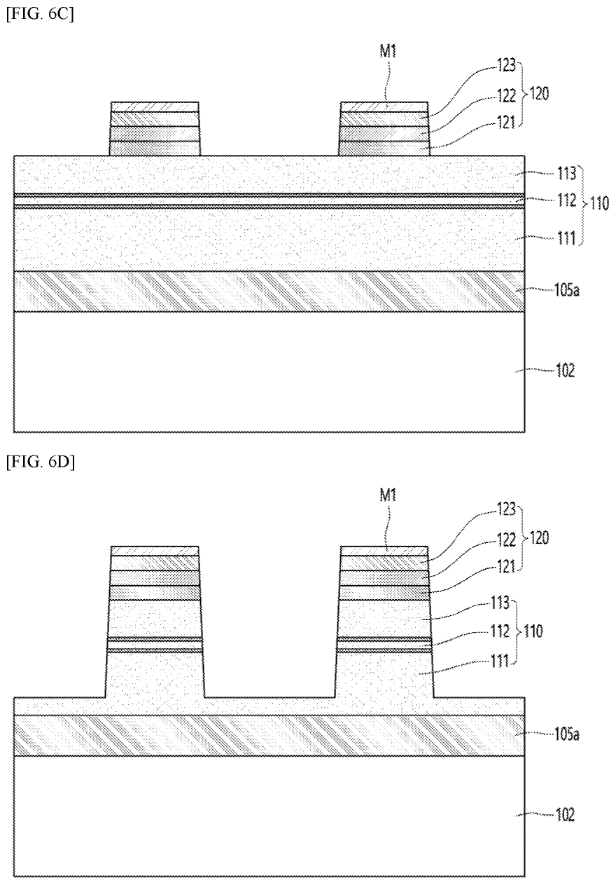

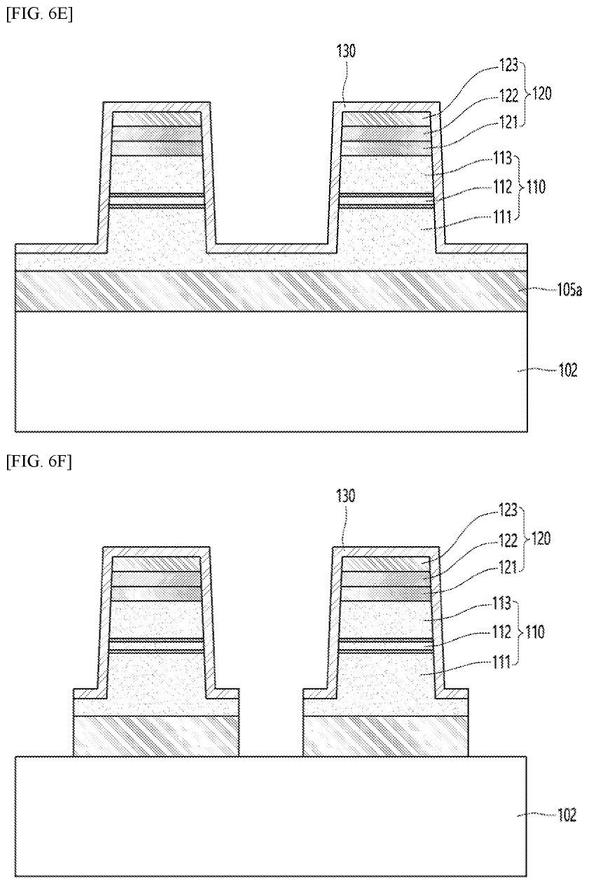

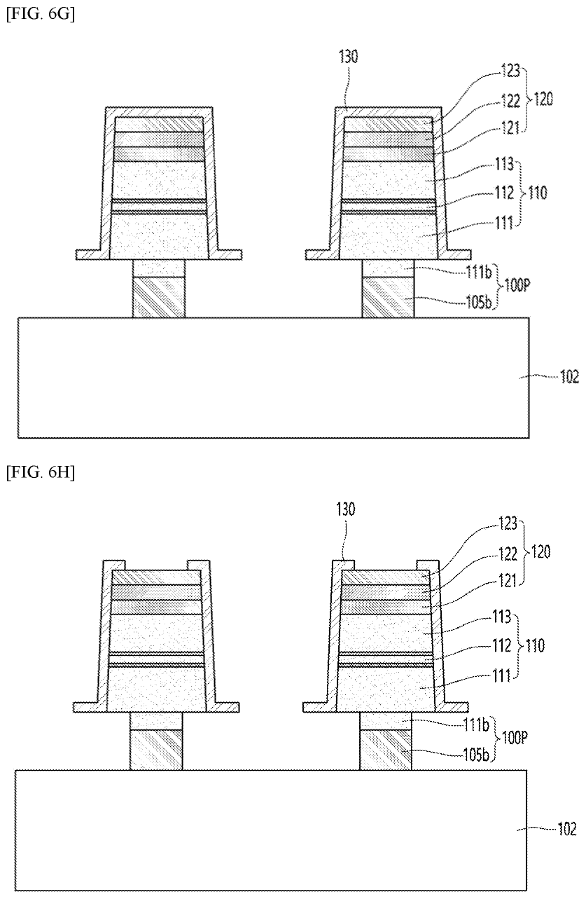

Next, FIGS. 6A to 6H are cross-sectional views of a manufacturing method of a semiconductor light emitting device according to an embodiment.

First, referring to FIG. 6A, the undoped semiconductor layer 105 and the light emitting structure 110 can be sequentially formed on the growth substrate 102. The growth substrate 102 can be a sapphire substrate or a GaN substrate, but is not limited thereto. The undoped semiconductor layer 105 can be a GaN-based semiconductor layer and dopants may not be implanted, but dopants can be diffused in subsequent processes.

The light emitting structure 110 can include the first conductivity type semiconductor layer 111, the active layer 112, and the second conductivity type semiconductor layer 113 as described above.

Next, as shown in FIG. 6B, a second electrode layer 120 including a transparent electrode layer 121, a reflective layer 122, and a magnetic layer 123 can be formed on the light emitting structure 110.

Next, as shown in FIG. 6C, the second electrode layer 120 can be partially etched by forming the first mask pattern M1 as an etch mask. Etching of the second electrode layer 120 can be performed by dry etching, but is not limited thereto.

Next, as shown in FIG. 6D, the light emitting structure 110 can be partially dry etched using the first mask pattern M1 as an etch mask, but is not limited thereto. Of the light emitting structure 110, the second conductivity type semiconductor layer 113 and the active layer 112 are visible, and a portion of the first conductivity type semiconductor layer 111 can remain.

Next, as shown in FIG. 6E, the insulating layer 130 can be formed after removing the first mask pattern M1. The insulating layer 130 can be an oxide film or a nitride film, but is not limited thereto.

Next, as shown in FIG. 6F, the growth substrate 102 can be exposed by etching the insulating layer 130, the remaining first conductivity-type semiconductor layer 111, and the undoped semiconductor layer 105.

Next, as shown in FIG. 6G, the protruding mesa semiconductor layer 100P can be formed by wet etching the exposed first conductivity type semiconductor layer 111 and the undoped semiconductor layer 105 not covered by the insulating layer 130 with KOH or the like. The protruding mesa semiconductor layer 100P can include a first conductivity type mesa semiconductor layer 111b and an undoped mesa semiconductor layer 105b.

Next, as shown in FIG. 6H, a portion of the insulating layer 130 can be etched to expose the magnetic layer 123 in the second electrode layer 120.

Thereafter, the growth substrate 102 can be removed using LLO or the like to complete the semiconductor light emitting device 150R according to the embodiment shown in FIG. 5.

According to the semiconductor light emitting device and the display device including the same according to the embodiment, in transferring the semiconductor light emitting devices to the display panel, the transfer speed and the transfer yield can be simultaneously improved, and as the protruding mesa structure is disposed in the area opposite to p-GaN, there is a technical effect of increasing transfer and assembly efficiency without position crosstalk during direct self-assembly.

Also, according to the embodiment, the light emitting area of the light emitting device chip can be implemented as the maximum area and a structure having a highly reflective metal layer is implemented, also to maximizing the luminous efficiency, there is a technical effect capable of providing a micro LED chip structure with ultra-high-speed direct self-assembly and transfer function using an electromagnetic field.

Also, according to the embodiment, the passivation layer is formed on the side surface of the second conductivity type semiconductor layer and a part of the side surface and bottom surface of the second electrode layer, thereby providing a structure resistant to collision between chips and external impact during self-assembly.

Also, according to the embodiment, by forming the passivation layer on the top and side surfaces of the p-GaN area of the light emitting chip, there is a technical effect of maximizing light emitting efficiency with side-effects of the subminiature LED chip.

Also, according to the embodiment, there is a technical effect of improving light extraction efficiency while implementing an ultra-thin micro-LED display.

### Second Example

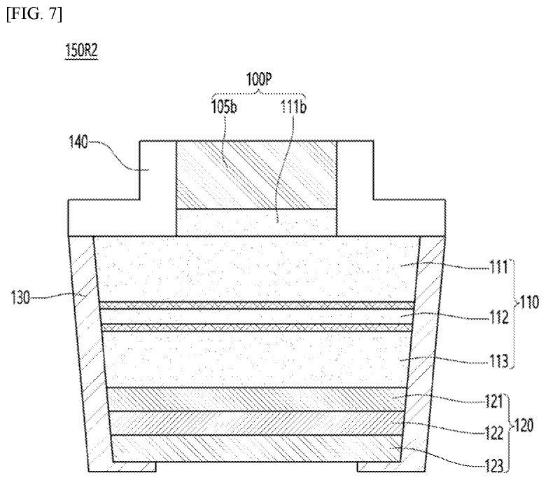

Next, FIG. 7 is a cross-sectional view of the semiconductor light emitting device 150R2 according to the second embodiment.

The second embodiment can employ the technical features of the first embodiment, and the main features of the second embodiment will be mainly described below.

The semiconductor light emitting device 150R2 according to the second embodiment can include the light extraction structure 140 disposed on the side surface of the protruding mesa semiconductor layer 100P. The light extraction structure 140 can be formed of an insulating layer or a metal layer. For example, the light extracting structure 140 can be DBR or the like or Ag, Ni, Al, etc., but is not limited thereto.

According to the second embodiment, since the light extraction structure 140 is disposed on the side surface of the protruding mesa semiconductor layer 100P, there is a technical effect of enabling directional light extraction. The light extraction structure 140 can also be formed on an upper surface of the first conductivity type semiconductor layer 111.

When the light extraction structure 140 is formed of an insulating material, the first pad electrode 221 can be electrically connected to the first conductivity type semiconductor layer 111 through a predetermined pad opening process.

On the other hand, when the light extraction structure 140 is formed of a reflective material of a metal material, the first pad electrode 221 can be electrically connected to the first conductivity type semiconductor layer 111 by contacting the light extraction structure 140 without the need for a predetermined pad opening process. The light extraction structure 140 increases the electrical contact area with the pad electrode along with the optical effect of light extraction, so that the electrical characteristics are also improved.

### Third Embodiment

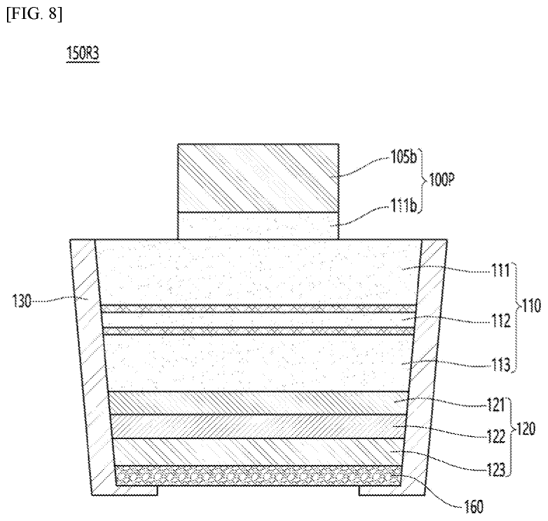

Next, FIG. 8 is a cross-sectional view of the semiconductor light emitting device 150R3 according to the third embodiment.

The third embodiment can employ technical features of the first or second embodiment, and the main features of the third embodiment will be mainly described below.

The semiconductor light emitting device 150R3 according to the third embodiment can further include a second solder layer 160 disposed below the second electrode layer 120.

According to the third embodiment, as the second solder layer 160 is disposed below the second electrode layer 120, the bonding force between the semiconductor light emitting device and the second pad electrode 222 of the pad substrate is improved, thereby improving reliability.

According to the semiconductor light emitting device and the display device including the same according to the embodiment, in transferring semiconductor light emitting devices to a display panel, it is possible to simultaneously improve transfer speed and transfer yield, as the protruding mesa structure is disposed in the area opposite to p-GaN, there is a technical effect of increasing transfer and assembly efficiency without position crosstalk during direct self-assembly.

Also, according to the embodiment, the light emitting area of the light emitting device chip can be implemented as the maximum area and a structure having a highly reflective metal layer can be implemented. Accordingly, there is a technical effect capable of providing an ultra-small size micro LED chip structure having a high-speed direct self-assembly transfer function using an electromagnetic field as well as maximizing luminous efficiency.

Also, according to the embodiment, the passivation layer is formed on the side surface of the second conductivity type semiconductor layer and a part of the side surface and bottom surface of the second electrode layer, thereby providing a structure resistant to collision between chips and external impact during self-assembly.

Also, according to the embodiment, by forming the passivation layer on the top and side surfaces of the p-GaN area of the light emitting chip, there is a technical effect of maximizing light emitting efficiency with side-effects of the subminiature LED chip.

According to the embodiment, there is a technical effect of improving light extraction efficiency while implementing an ultra-thin micro-LED display.

### INDUSTRIAL APPLICABILITY

The semiconductor light emitting device according to the embodiment is not limited to the micro LED, and includes mini LED.

The semiconductor light emitting device according to the embodiment can be applied to an LED having a relatively large area for illumination and signage also to the micro LED display.

Also, a semiconductor light emitting device according to an embodiment and a display device including the same can include Digital TVs, mobile phones, smart phones, laptop computers, digital broadcasting terminals, PDAs (personal digital assistants), a PMP (portable multimedia player), a navigation, a slate PC, a tablet PC, an ultra-book, a desktop computer, etc.

The above description is merely an example of the technical idea of the embodiment, and various modifications and variations can be made to those skilled in the art without departing from the essential characteristics of the embodiment.

Accordingly, the disclosed embodiments are not intended to limit the technical idea of the embodiment but to explain, and the scope of the technical idea of the embodiment is not limited by these examples.

The protection scope of the embodiment should be interpreted according to the claims below, and all technical ideas within the scope equivalent thereto should be construed as being included in the scope of rights of the embodiment.

1. A semiconductor light emitting device comprising:
a second electrode layer;
a light emitting structure disposed on the second electrode layer;
a protruding mesa semiconductor layer disposed on the light emitting structure; and
a passivation layer disposed on a side surface of the light emitting structure,
wherein the protruding mesa semiconductor layer comprises a first conductivity type mesa semiconductor layer and an undoped mesa semiconductor layer.

2. The semiconductor light emitting device according to claim 1, wherein the second electrode layer comprises a transparent electrode layer disposed on the light emitting structure, a reflective layer disposed on the transparent electrode layer, and a magnetic layer disposed on the reflective layer.

3. The semiconductor light emitting device according to claim 1, wherein a horizontal width of the protruding mesa semiconductor layer is smaller than a horizontal width of the light emitting structure.

4. The semiconductor light emitting device according to claim 1, wherein a horizontal width of the protruding mesa semiconductor layer is smaller than a horizontal width of the second electrode layer.

5. The semiconductor light emitting device according to claim 1, wherein a horizontal width of the protruding mesa semiconductor layer is smaller than a horizontal width of the light emitting structure or a horizontal width of the second electrode layer,
wherein the second electrode layer comprises a magnetic material, and
wherein the protruding mesa semiconductor layer does not comprise a magnetic material.

6. The semiconductor light emitting device according to claim 1, wherein a height of the protruding mesa semiconductor layer is smaller than a height of the light emitting structure.

7. The semiconductor light emitting device according to claim 1, wherein a horizontal width of the protruding mesa semiconductor layer is smaller than a horizontal width of the second electrode layer.

8. The semiconductor light emitting device according to claim 1, wherein the passivation layer is disposed on a side surface of the second conductivity type semiconductor layer of the light emitting structure and a part of the side surface and bottom surface of the second electrode layer.

9. The semiconductor light emitting device according to claim 1, wherein the protruding mesa semiconductor layer disposed on the light emitting structure is configured to improve light extraction efficiency by a photonic crystal function.

10. The semiconductor light emitting device according to claim 1, further comprising a light extraction structure disposed on a side surface of the protruding mesa semiconductor layer.

11. The semiconductor light emitting device according to claim 10, wherein the light extraction structure includes a reflective material of a metal material and is electrically connected to the first conductive semiconductor layer of the light emitting structure by contacting the first pad electrode.

12. The semiconductor light emitting device according to claim 1, further comprising a second solder layer disposed below the second electrode layer.

13. A display device comprising:
a panel substrate including a first wiring electrode and a second wiring electrode; and
the semiconductor light emitting device package according to claim 1 disposed on the panel substrate.

14. The semiconductor light emitting device according to claim 1, wherein the light emitting structure comprises a first region contacting the protruding mesa semiconductor layer and a second region not contacting the protruding mesa semiconductor layer.

15. The semiconductor light emitting device according to claim 1, wherein the passivation layer is in contact with the side surface of the light emitting structure and is not in contact with the top surface thereof.

16. The semiconductor light emitting device according to claim 15, wherein an upper surface of the passivation layer is located at the same height as the upper surface of the light emitting structure.

17. The semiconductor light emitting device according to claim 1, wherein a horizontal width decreases from the light emitting structure toward the second electrode layer.

18. A display device including a semiconductor light emitting device comprising:
a substrate;
a first wiring electrode and a second wiring electrode disposed on the substrate;
an insulating layer disposed on the first wire electrode and the second wire electrode;
a barrier wall disposed on the insulating layer and having an assembly hole; and
a semiconductor light emitting device disposed in the assembly hole,
wherein the semiconductor light emitting device comprises a second electrode layer; a light emitting structure disposed on the second electrode layer; a protruding mesa semiconductor layer disposed on the light emitting structure; and a passivation layer disposed on a side surface of the light emitting structure, and
wherein the protruding mesa semiconductor layer comprises a first conductivity type mesa semiconductor layer and an undoped mesa semiconductor layer.

19. The display device including a semiconductor light emitting device according to claim 18, wherein the light emitting structure comprises a first region contacting the protruding mesa semiconductor layer and a second region not contacting the protruding mesa semiconductor layer.

20. The display device including a semiconductor light emitting device according to claim 19, further comprising a panel wiring connected to the second region.
